(19) United States
(12) Patent Application Publication
(10) Pub. No.: US 2026/0358386 A1
(43) Pub. Date: Nov. 12, 2026

(54) CURRENT SIGNAL DETECTION SYSTEM

(71) Applicants: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(72) Inventors: Yu GONG, Guangzhou (CN); Wenbin YAN, Guangzhou (CN); Guancheng QUAN, Guangzhou (CN); Yongqi LI, Guangzhou (CN); Qing LI, Guangzhou (CN); Minggang ZHU, Guangzhou (CN); Hang NIE, Guangzhou (CN); Qiang CHEN, Guangzhou (CN); Lei ZHANG, Guangzhou (CN); Xiaoliang LI, Guangzhou (CN); Xiao LIANG, Guangzhou (CN); Peng WANG, Guangzhou (CN); Jun JIANG, Guangzhou (CN); Xiangwei HUANG, Guangzhou (CN); Sijie WANG, Guangzhou (CN); Peng LING, Guangzhou (CN)

(73) Assignees: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(21) Appl. No.: 19/489,460

(22) PCT Filed: Dec. 16, 2024
(86) PCT No.: PCT/CN2024/139512

§ 371 Date: Dec. 2, 2025

(30) Foreign Application Priority Data
Dec. 18, 2023 (CN) 202311742767.7

(51) Int. Cl. G01R 19/25; G01R 31/08

(52) U.S. Cl. CPC G01R 19/2513; G01R 31/088

(57) ABSTRACT

A current signal detection system is provided. The current signal detection system comprises: at least two current signal detection units, wherein the current signal detection units are respectively arranged at different positions of a target detection cable in a power system and are electrically connected by means of the target detection cable, each current signal detection unit is used for acquiring a target current signal flowing through the current signal detection unit in the target detection cable so as to determine a current signal detection result of the target detection cable on the basis of the target current signal corresponding to the current signal detection unit, and the current signal detection result comprises an abnormal working state of the target detection cable. The current signal detection system can improve the fault monitoring efficiency of the power system.

### CROSS-REFERENCE TO RELATED APPLICATIONS

This application is a U.S. National Stage Application, filed under 35 U.S.C. 371, of International Patent Application No. PCT/CN2024/139512, filed on Dec. 16, 2024, which claims priority to Chinese Patent Application No. 202311742767.7, filed on Dec. 18, 2023, the entire contents of which are incorporated herein by reference.

### TECHNICAL FIELD

The present disclosure relates to the technical field of electronic devices, and in particular, to a current signal detection system.

### BACKGROUND

In the field of fault monitoring of a power system, there is a need to collect and monitor data from power devices or lines in the power systems, such as collect current data, to assess a current operating state of the system, thereby enabling timely remedial measures in case of abnormal system data.

However, current monitoring means for abnormal system data require an engineer to be stationed on-site, using data detection tools to measure at designated positions and record data, which results in low data acquisition efficiency and leads to poor performance of fault monitoring of the power system.

### SUMMARY

Based on this, there is a need to provide, with respect to the above technical problem, a current signal detection system that can improve fault monitoring efficiency of the power system.

The present disclosure provides a current signal detection system, where the current signal detection system includes:
at least two current signal detection units, where the signal detection units are respectively arranged at different positions of a target detection cable in a power system, and the current signal detection units are electrically connected via the target detection cable;
where each current signal detection unit is configured for acquiring a target current signal, flowing through the current signal detection unit, in the target detection cable, and a current signal detection result of the target detection cable is determined on the basis of the target current signals corresponding to the current signal detection units; and the current signal detection result includes an abnormal working state of the target detection cable.

In an embodiment, the current signal detection unit includes:
at least one detachable functional module, where the functional module is configured for transmitting and collecting the target current signal flowing through the current signal detection unit in the target detection cable; and
in a case where the target detection cable is a power cable, the functional module is a power cable module; in a case where the target detection cable is an optical cable, the functional module is an optical cable module; and in a case where the target detection cable is a network cable, the functional module is a network module.

In an embodiment, the current signal detection unit includes:
a processor, where the processor is connected to the functional module, and the processor is configured to process the collected target current signal to determine the current signal detection result of the target detection cable.

In an embodiment, in the case where the target detection cable is the optical cable, the current signal detection unit further includes:
a photoelectric conversion module, where the photoelectric conversion module is connected to the optical cable module and the processor separately;
the photoelectric conversion module is configured for converting an optical signal in the optical cable module into an electrical signal, to determine the target current signal.

In an embodiment, the current signal detection unit further includes:
a line state control module, where the line state control module is connected to the processor and the functional module; and
the line state control module is configured for adjusting a line state by setting a connection condition of each functional module, and transmitting the line state to the processor, the line state including a disconnected state, a connected state, a bypass state, and a jumper state.

In an embodiment, the current signal detection unit further includes:
a communication module, where the communication module is connected to the processor, and the communication module is configured to communicatively connect with a target device, and send the line state and the current signal detection result to the target device;
the target device is configured for allowing a user to view the line state and the current signal detection result, and the target device includes a mobile terminal associated with the current signal detection system.

In an embodiment, the current signal detection unit further includes:
a first state indication module, where the first state indication module is connected to the processor, and the first state indication module is configured for displaying the line state; and
a second state indication module, where the second state indication module is connected to the processor, and the second state indication module is configured for displaying the current signal detection result.

In an embodiment, each functional module in the current signal detection unit employs one set of target cables as signal input and at least two sets of target cables as signal output. Each target cable set includes three sub-cables and a ground wire, with a phase difference of 120 degrees between signals transmitted in every two of the three sub-cables.

In an embodiment, the current signal detection unit is electrically connected to the target detection cable by means of a snap spring; and
the current signal detection unit further includes a snap spring connection state monitoring module, where the snap spring connection state monitoring module is configured for recording a working state of the snap spring.

In an embodiment, the current signal detection unit further includes:
an identity authentication module, where the identity authentication module is configured for authenticating identity of a user and enabling a detection function of the current signal detection unit in a case where identity authentication on the user is successful.

According to the above current signal detection system, the current signal detection system includes at least two current signal detection units, the signal detection units are respectively arranged at different positions of a target detection cable in a power system, and the current signal detection units are electrically connected via the target detection cable. In the current signal detection system in the present disclosure, in the manner of arranging current signal detection units at different positions of a same cable, both a data collection efficiency and a condition response speed are enhanced based on a relationship between current values detected by different current signal detection units rather than through a manual detection process and a manual data recording process, thereby improving a fault monitoring efficiency of the power system.

### BRIEF DESCRIPTION OF THE DRAWINGS

FIG. 1 is a first schematic structural diagram of a current signal detection system according to an embodiment;

FIG. 2 is a second schematic structural diagram of a current signal detection system according to an embodiment;

FIG. 3 is a first schematic structural diagram of a current signal detection unit according to an embodiment; and

FIG. 4 is a second schematic structural diagram of a current signal detection unit according to an embodiment.

### DETAILED DESCRIPTION

To make the objectives, technical solutions, and advantages of the present disclosure more comprehensible, the present disclosure is described in further detail below according to embodiments with reference to the accompanying drawings. It should be understood that specific embodiments described herein are merely illustrative for the present disclosure and are not intended to limit the present disclosure.

It should be noted that user information (including, but not limited to, information of a user device, and user personal information) and data (including, but not limited to, data for analysis, stored data, and displayed data) as referred to in the present disclosure are all information and data authorized by users or fully authorized by all parties, and the collection, use, and processing of relevant data need to comply with relevant laws, regulations, and standards of relevant countries and regions.

In an embodiment, a current signal detection system is provided, including: at least two current signal detection units.

The signal detection units are respectively arranged at different positions of a target detection cable in a power system, and the current signal detection units are electrically connected via the target detection cable. Specifically, the target detection cable is a cable under test.

The current signal detection unit is configured for acquiring a target current signal, flowing through the current signal detection unit, in the target detection cable, and accordingly, a current signal detection result of the target detection cable can be determined on the basis of target current signals corresponding to the respective current signal detection units. Specifically, the target current signal may be a current signal obtained through direct measurement, a current signal converted from a detected optical signal, or a current signal converted from a detected network signal.

The current signal detection result includes an abnormal working state of the target detection cable.

Exemplarily, the signal detection units are respectively arranged at different positions of the target detection cable in the power system, for example, connected in series at different positions of a same cable. Under normal conditions without any unauthorized cable connections, currents detected by the respective signal detection units are equal. If the detected currents are not equal, an abnormal condition such as an unauthorized cable connection may exist. In this case, the current signal detection result is determined to be the abnormal working state of the target detection cable, which alerts monitoring personnel to conduct timely investigation and handling, thereby achieving monitoring on the target detection cable.

In the above current signal detection system, the current signal detection system includes at least two current signal detection units, the signal detection units are respectively arranged at different positions of the target detection cable in the power system, and the current signal detection units are electrically connected via the target detection cable. In the current signal detection system in the present disclosure, in the manner of arranging current signal detection units at different positions of a same cable, both a data collection efficiency and a condition response speed are enhanced based on a relationship between current values detected by different current signal detection units rather than through a manual detection process and a manual data recording process, thereby improving a fault monitoring efficiency of the power system.

In an embodiment, the current signal detection unit includes at least one detachable functional module. The at least one functional module is configured for transmitting and collecting the target current signal flowing through the current signal detection unit in the target detection cable. In a case where the target detection cable is a power cable, the functional module is a power cable module. In a case where the target detection cable is an optical cable, the functional module is an optical cable module. In a case where the target detection cable is a network cable, the functional module is a network module.

In the embodiment, the current signal detection unit includes at least one detachable functional module configured for transmitting and collecting the target current signal flowing through the current signal detection unit in the target detection cable. By arranging different types of functional modules, different types of cables can be monitored. At the same time, the detachability of the functional module enhances its applicability for diverse power system fault monitoring scenarios.

In an embodiment, the current signal detection unit includes a processor. The processor is connected to the functional module, and the processor is configured to process the collected target current signal to determine the current signal detection result of the target detection cable.

In the embodiment, the current signal detection unit includes the processor, which serves as an information processing center and is connected to various functional modules to process the collected current signal. The collected current signal is analyzed, achieving monitoring on the working state.

In an embodiment, in the case that the target detection cable is the optical cable, the current signal detection unit further includes a photoelectric conversion module. The photoelectric conversion module is connected to the optical cable module and the processor separately. The photoelectric conversion module is configured for converting an optical signal in the optical cable module into an electrical signal, to determine the target current signal.

In the embodiment, the current signal detection unit further includes the photoelectric conversion module, which is connected to the optical cable module and the processor separately and is configured for converting the optical signal in the optical cable module into the electrical signal, to determine the target current signal, achieving conversion from the optical signal to the electrical signal. Data analysis can be performed by using the electrical signal obtained by conversion, thereby enhancing the applicability for diverse power system fault monitoring scenarios.

In an embodiment, the current signal detection unit further includes a line state control module. The line state control module is connected to the processor and the functional module. The line state control module is configured for adjusting a line state by setting a connection condition of each functional module, and transmitting the line state to the processor. The line state includes a disconnected state, a connected state, a bypass state, and a jumper state.

For example, the current signal detection unit includes an operating mechanism or an operating module which can perform disconnecting, connecting, bypassing, and jumper functions.

In the embodiment, the current signal detection unit further includes the line state control module. By configuring the connection condition of each functional module to adjust the line state and transmitting the line state to the processor, control over the line state is achieved, thereby enabling individual control over each current signal detection unit in the current signal detection system and helping to improve operational efficiency of the current signal detection system.

In an embodiment, the current signal detection unit further includes a communication module. The communication module is connected to the processor. The communication module is configured for communicatively connecting with a target device, and sending the line state and the current signal detection result to the target device. The target device is configured for allowing a user to view the line state and the current signal detection result. The target device includes a mobile terminal associated with the current signal detection system.

For example, a CPU may be connected to a mobile phone APP, allowing state viewing but not allowing program modification. The CPU is provided with a necessary indicator light configured for identifying a power state, an operating state, and a fault state.

In the embodiment, the current signal detection unit further includes the communication module which is used for sending the line state and the current signal detection result to the target device, allowing the user to view the line state and the current signal detection result, which achieves communication between each current signal detection unit and an external mobile terminal and implement data transmission and control by using data communication, thereby improving the fault monitoring efficiency of the power system.

In an embodiment, the current signal detection unit further includes a first state indication module and a second state indication module. The first state indication module is connected to the processor, and is configured for displaying the line state. The second state indication module is connected to the processor, and is configured for displaying the current signal detection result.

In the embodiment, the first state indication module and the second state indication module are arranged to respectively display the line state and the current signal detection result, thereby improving intuitiveness of fault monitoring of the power system.

In an embodiment, each functional module in the current signal detection unit employs one set of target cables as signal input and at least two sets of target cables as signal output. Each target cable set includes three sub-cables and a ground wire, with a phase difference of 120 degrees between signals transmitted in every two of the three sub-cables.

For example, one module can be connected to only one set including three-phase lines and a neutral line (N line) as input, and can be connected to at least two sets each including three-phase lines and an N line as output.

In an embodiment, the current signal detection unit is electrically connected to the target detection cable by means of a snap spring, and the current signal detection unit further includes a snap spring connection state monitoring module. The snap spring connection state monitoring module is configured for recording a working state of the snap spring.

In the embodiment, the snap spring is arranged at a junction, and the snap spring connection state monitoring module is arranged at the snap spring, to record and monitor the working state of the snap spring. In this way, stability of operation of the current signal detection unit after its mounting can be ensured, thereby enhancing the stability of fault monitoring of the power system.

In an embodiment, the current signal detection unit further includes an identity authentication module. The identity authentication module is configured for authenticating identity of a user, and enabling a detection function of the current signal detection unit in a case where identity authentication on the user is successful.

In the embodiment, the current signal detection unit further includes the identity authentication module which is configured for enabling the detection function of the current signal detection unit in the case where identity authentication on the user is successful, which achieves authentication on a control permission of each current signal detection unit, thereby ensuring security of fault monitoring of the power system.

For ease of understanding by those skilled in the art, FIG. 1 provides a first schematic structural diagram of a current signal detection system. As shown in FIG. 1, I_{A}=I_{B}=I_{C}, where I_{A} denotes a current value of Unit A, I_{B} denotes a current value of Unit B, and I_{C} denotes a current value of Unit C. FIG. 1 shows that, under a normal operating condition with only one cable line and no abnormal unauthorized circuits, in a case where the current values collected by current signal detection units connected in series in the cable are the same, the current signal detection result is determined to indicate that the target detection cable is in a normal working state. In a case where the current values collected by the current signal detection units connected in series in the cable are different, the current signal detection result is determined to indicate that the target detection cable is in an abnormal working state.

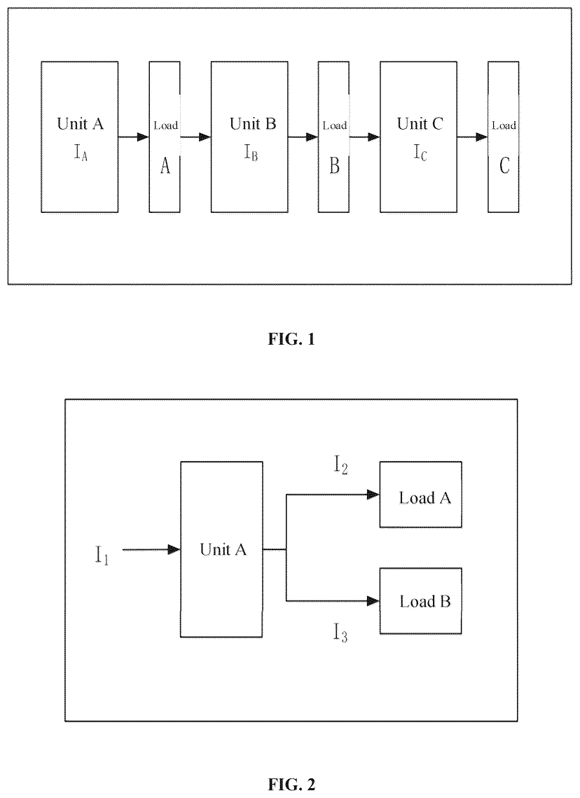

For ease of understanding by those skilled in the art, FIG. 2 provides a second schematic structural diagram of a current signal detection system. As shown in FIG. 2, I₁=I₂+I₃, where I₁ denotes a current into Unit A, I₂ denotes a current from Unit A to Load A, and I₃ denotes a current from Unit A to Load B. FIG. 2 shows that, under a normal operating condition with two cable branches and no abnormal unauthorized circuits, in a case where a sum of current values collected by output branches connected in parallel in the cable of the current signal detection unit is equal to a total current value of an input branch, the current signal detection result is determined to indicate that the target detection cable is in a normal working state. Otherwise, the current signal detection result is determined to indicate that the target detection cable is in an abnormal working state.

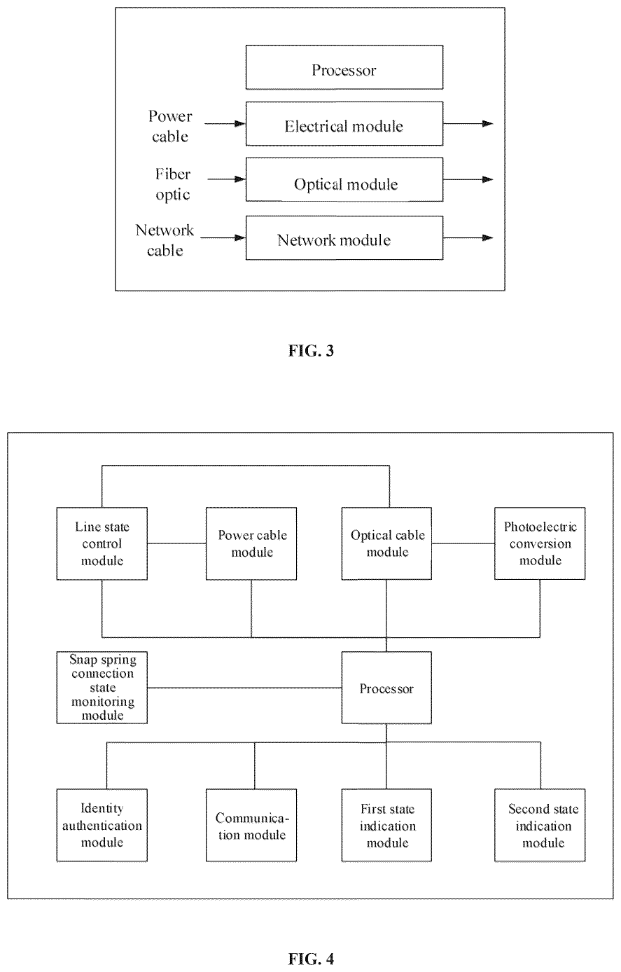

For ease of understanding by those skilled in the art, FIG. 3 provides a first schematic structural diagram of a current signal detection unit. As shown in FIG. 3, the current signal detection unit includes a processor, an electrical module, an optical module, and a network module. The electrical module is configured for connection to a power cable, the optical module is configured for connection to a fiber optic, and the network module is configured for connection to a network cable.

For ease of understanding by those skilled in the art, FIG. 4 provides a second schematic structural diagram of a current signal detection unit.

The current signal detection system is described in detail below with a specific embodiment. It should be noted that the following description is merely illustrative, rather than being a specific limitation on the present disclosure.

The current signal detection unit has the following features: (1) current signal detection is mounted on a guide rail; (2) an actuating mechanism or a photoelectric conversion module is provided inside; (3) the input are receivable electrical signals transmitted by means of the power cable, such as currents and voltages, optical signals transmitted by means of the fiber optic, or network signals transmitted by means of the communication cable; (4) the output corresponds to the input described in (3), that is, the output are receivable electrical signals transmitted by means of the power cable, such as currents and voltages, optical signals transmitted by means of the fiber optic, or network signals transmitted by means of the communication cable; (5) the input and the output may be modularly configured; (6) an operating mechanism or module is provided inside, which can perform disconnecting, connecting, bypassing, and jumper functions; (7) each intelligent current detection unit includes a CPU (often called the “brain”) and an integrated module; (8) the CPU may be connected to a mobile phone APP, allowing state viewing but not allowing program modification, and the CPU is provided with a necessary indicator light configured for identifying a power state, an operating state, and a fault state; (9) the module is provided with an indicator light configured for identifying a disconnected state, a connected state, a bypass state, and a fault state; (10) one module can be connected to only one set of three-phase lines +N line as input, and at least two sets of three-phase lines+N line as output; (11) the intelligent current detection unit employs a snap spring for connection; (12) the unit has temperature, acoustic, and humidity monitoring functions and detects a state of the snap spring; (13) the unit has an external communication function; and (14) prior to use, the unit requires independent unique identity authentication.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, and these all fall within the protection scope of the present disclosure. Therefore, the protection scope of the present disclosure should be subject to the appended claims.

1. A current signal detection system, comprising:
at least two current signal detection units, wherein the current signal detection units are respectively arranged at different positions of a target detection cable in a power system, and the current signal detection units are electrically connected via the target detection cable;
wherein each current signal detection unit is configured to acquire a target current signal, flowing through the current signal detection unit, in the target detection cable, and a current signal detection result of the target detection cable is determined on the basis of target current signals corresponding to the current signal detection units, the current signal detection result comprising an abnormal working state of the target detection cable;
wherein the current signal detection unit comprises:
at least one detachable functional module, wherein the at least one functional module is configured to transmit and collect the target current signal flowing through the current signal detection unit in the target detection cable; and
in a case where the target detection cable is a power cable, the functional module is a power cable module; in a case where the target detection cable is an optical cable, the functional module is an optical cable module; and in a case where the target detection cable is a network cable, the functional module is a network module;
wherein the current signal detection unit comprises:
a processor, wherein the processor is connected to the functional module, and the processor is configured to process the collected target current signal to determine the current signal detection result of the target detection cable; and
wherein the current signal detection unit further comprises:
a line state control module, wherein the line state control module is connected to the processor and the functional module; and
the line state control module is configured to adjust a line state by setting a connection condition of each functional module, and transmit the line state to the processor, wherein the line state comprises a disconnected state, a connected state, a bypass state, and a jumper state.

2. The current signal detection system according to claim 1, wherein in the case where the target detection cable is the optical cable, the current signal detection unit further comprises:
a photoelectric conversion module, wherein the photoelectric conversion module is connected to the optical cable module and the processor separately;
wherein the photoelectric conversion module is configured to convert an optical signal in the optical cable module into an electrical signal, to determine the target current signal.

3. The current signal detection system according to claim 1, wherein the current signal detection unit further comprises:
a communication module, wherein the communication module is connected to the processor, and the communication module is configured to communicatively connect with a target device, and send the line state and the current signal detection result to the target device;
wherein the target device is configured to allow a user to view the line state and the current signal detection result, and the target device comprises a mobile terminal associated with the current signal detection system.

4. The current signal detection system according to claim 1, wherein the current signal detection unit further comprises:
a first state indication module, wherein the first state indication module is connected to the processor, and the first state indication module is configured to display the line state; and
a second state indication module, wherein the second state indication module is connected to the processor, and the second state indication module is configured to display the current signal detection result.

5. The current signal detection system according to claim 1, wherein each functional module in the current signal detection unit employs one set of target cables as signal input and at least two sets of target cables as signal output, wherein each target cable set comprises three sub-cables and a ground wire, with a phase difference of 120 degrees between signals transmitted in every two of the three sub-cables.

6. The current signal detection system according to claim 1, wherein the current signal detection unit is electrically connected to the target detection cable by means of a snap spring; and
the current signal detection unit further comprises a snap spring connection state monitoring module, wherein the snap spring connection state monitoring module is configured to record a working state of the snap spring.

7. The current signal detection system according to claim 6, wherein the current signal detection unit further comprises:
an identity authentication module, wherein the identity authentication module is configured to authenticate identity of a user and enable a detection function of the current signal detection unit in a case where identity authentication on the user is successful.
